(19) United States
(12) Patent Application Publication
(10) Pub. No.: US 2026/0253851 A1
(43) Pub. Date: Aug. 27, 2026

(54) SUBSTRATE PROCESSING APPARATUS FOR DOUBLE-SIDED SPUTTERING

(71) Applicant: S.E.A Co., Ltd., Gyeongsangbuk-do (KR)

(72) Inventor: Jaeho Shin, Gumi-si (KR)

(21) Appl. No.: 19/235,119

(22) Filed: Jun. 11, 2025

(30) Foreign Application Priority Data
Feb. 27, 2025 (KR) 10-2025-0025683

(51) Int. Cl. H01J 37/32; C23C 14/34; C23C 14/50; H01J 37/34; H10P 72/30

(52) U.S. Cl. CPC H01J 37/32733; C23C 14/34; C23C 14/50; H01J 37/3464; H10P 72/3204; H01J 2237/20257; H01J 2237/332

(57) ABSTRACT

Disclosed are a sputtering unit that performs double-sided sputtering on both surfaces of a substrate in a vertical position while handling the substrate in the vertical position, a substrate processing apparatus including the same, and an operating method thereof.

### CROSS-REFERENCE TO RELATED APPLICATION

This application claims the benefit of priority under 35 U.S.C. § 119 to Korean Patent Application No. 10-2025-0025683 filed on February 27, 2025, in the Korean Intellectual Property Office (KIPO), the entire contents of which are incorporated herein by reference.

### BACKGROUND

### Technical Field

The following embodiments relate to a substrate processing apparatus for double-sided sputtering.

### Background of the Invention

A substrate processing apparatus is used to perform a surface processing step of sputtering such as circuit formation or plating on a product such as a substrate.

Such a substrate processing apparatus usually performs a transfer and sputtering process on a substrate in a horizontal position (a position in which a plane direction of the substrate is a vertical direction). Accordingly, an existing substrate processing apparatus has a disadvantage in that a large amount of space for equipment is required, and a substrate in a horizontal position is sputtered only on an upper surface of a flat surface, resulting in poor productivity. A technique for an existing substrate processing apparatus is disclosed in Korean Patent Application Publication No. 10-2005-0032251.

Accordingly, a technique for improving productivity and miniaturization of a substrate processing apparatus needs to be proposed.

### SUMMARY

In order to improve productivity and miniaturization of a substrate processing apparatus that performs a sputtering process, one embodiment propose a sputtering unit that performs double-side sputtering on both surfaces of a substrate in a vertical position while handling the substrate in the vertical position, a substrate processing apparatus including the same, and an operating method thereof.

In addition, in order to minimize contamination of a substrate due to particles in the process of transferring the substrate in a vertical position, one embodiment propose a substrate transferring unit using magnetic levitation, a substrate processing apparatus including the same, and an operating method thereof.

However, the technical problems to be solved by the present invention are not limited to the above problems, and may be variously extended without departing from the technical spirit and scope of the present invention.

### Method for Solving Problem

According to an embodiment, a substrate processing apparatus may include: a substrate transferring unit that transfers a substrate in a vertical position to a sputtering unit using magnetic levitation; and the sputtering unit that performs double-side sputtering on both surfaces of the substrate in the vertical position while being connected to one side of the substrate transferring unit.

According to one aspect, the substrate transferring unit may be configured to magnetically levitate a tray on which the substrate in the vertical position is coupled from a rail and transfer it to the sputtering unit.

According to another aspect, the tray may include: a magnetic generation module having an opposite polarity to the rail, and have a structure that prevents a magnetic field generated in the magnetic generation module or the rail from affecting the substrate in the vertical position.

According to another aspect, the tray may include: a blocking protrusion structure that blocks the magnetic field from below to prevent the magnetic field generated in the magnetic generation module or the rail from affecting the substrate in the vertical position. According to still another aspect, the vertical position of the substrate may mean a posture in which a plane direction of the substrate is a horizontal direction.

According to another aspect, the vertical position of the substrate may mean a position in which a plane direction of the substrate is a horizontal direction.

According to another aspect, the sputtering unit may perform the double-sided sputtering by yaw-rotating and repeatedly providing the substrate in the vertical position with at least one sputtering chamber configured to sputter a target on one side in a horizontal direction.

According to another aspect, the sputtering unit may initially provide the substrate in the vertical position to the at least one sputtering chamber so that any one of both surfaces of the substrate in the vertical position faces one side of the horizontal direction sputtering the target in the at least one sputtering chamber, yaw-rotate the substrate in the vertical position by 180° in a rotating chamber provided independently from the sputtering chamber, and then again provide the substrate in the vertical position to the at least one sputtering chamber so that the other one of the both surfaces of the substrate in the vertical position faces one side of the horizontal direction sputtering the target in the at least one sputtering chamber, thereby performing the double-side sputtering.

According to another aspect, the sputtering unit may perform the double-sided sputtering by repeatedly providing that both surfaces of the substrate in the vertical position alternately face one side in the horizontal direction sputtering the target in the at least one sputtering chamber, using a cross design of rails for transferring the substrate in the vertical position.

According to another aspect, the substrate transferring unit may further include: a buffer for temporarily storing the substrate in the vertical position.

According to an embodiment, a substrate processing method of a substrate processing apparatus may include: a step of transferring, in a substrate transferring unit included in the substrate processing apparatus, a substrate in a vertical position to a sputtering unit included in the substrate processing apparatus using magnetic levitation; and a step of performing, in the sputtering unit connected to one side of the substrate transferring unit, double-sided sputtering on both surfaces of the substrate in the vertical position.

### Effects of the Invention

Embodiments propose a sputtering unit that performs double-side sputtering on both surfaces of a substrate in a vertical position while handling the substrate in the vertical position, a substrate processing apparatus including the same, and an operating method thereof, thereby making it possible to improve productivity and miniaturization of the substrate processing apparatus that performs a sputtering process.

In addition, embodiments propose a substrate transferring unit that utilizes magnetic levitation in the process of transferring a substrate in a vertical position, a substrate processing apparatus including the same, and an operating method thereof, thereby minimizing contamination of the substrate due to particles.

However, the effects of the present invention are not limited to the above effects, and may be variously extended without departing from the technical spirit and scope of the present invention.

### BRIEF DESCRIPTION OF THE DRAWINGS

FIG. 1 is a plan view illustrating a substrate processing apparatus according to an embodiment.

FIGS. 2 to 5 are enlarged plan views of a portion of a sputtering unit to illustrate a rotation function of a rotating chamber in the sputtering unit according to an embodiment.

FIG. 6 is an enlarged front view of a portion of a substrate transferring unit to illustrate the substrate transferring unit according to an embodiment.

FIG. 7 is a flowchart illustrating a substrate processing method according to an embodiment.

### DETAILED DESCRIPTION

Hereinafter, embodiments of the present invention will be described in detail with reference to the accompanying drawings so that those skilled in the art can easily implement the embodiments. Since the description of the present invention is merely an example for structural or functional description, the scope of the present invention should not be construed as being limited by the example described in the text.

That is, it should be understood that the scope of the present invention includes equivalents that can realize the technical idea, because the present invention is not limited to the embodiments described herein because various changes are possible and various different forms can be implemented.

On the other hand, the meaning of the terms described in the present invention should be understood as follows.

The terms “first,” “second,” and the like are intended to distinguish one component from another, and the scope of rights should not be limited by these terms. For example, a first component may be termed a second component, and similarly a second component may also be termed a first component.

When a component is referred to as being “connected” to another component, it should be understood that it may be directly connected to that other component, but there may be another component in the middle. On the other hand, when it is stated that a component is “directly connected” to another component, it should be understood that there is no other component in the middle. On the other hand, other expressions describing the relationship between the components, i.e., “between” and “directly between” or “neighboring to” and “direct neighboring to”, etc., should be construed as well.

It is to be understood that the singular forms “a,” “an,” and “the” include plural referents unless the context clearly dictates otherwise, and that the terms “comprises” or “has” or the like are intended to designate the presence of an embodied feature, number, step, operation, component, part, or combination thereof, and do not preclude the presence or possibility of addition of one or more other features, numbers, steps, operations, components, parts, or combinations thereof.

For each step, an identification code (e.g., a, b, c, etc.) is used for convenience of description, and the identification code does not describe the order of each of the steps, and each of the steps may occur differently from the specified order unless the context clearly describes a specific order. That is, each of the steps may occur in the same order as specified, may be performed substantially simultaneously, or may be performed in the opposite order.

Unless defined otherwise, all terms used herein have the same meaning as commonly understood by one of ordinary skill in the art to which this invention belongs. Terms defined in commonly used dictionaries should be interpreted as being consistent with their meaning in the context of the relevant art and cannot be interpreted as having an ideal or overly formal meaning unless expressly defined herein.

It is noted that the figures are schematic and not drawn to scale. The relative dimensions and proportions of the portions in the figures are shown exaggerated or reduced in size for clarity and convenience in the figures and any dimensions are illustrative only and not limiting. And to the same structures, elements, or components shown in more than one figure, the same reference numerals are used to indicate similar features.

The embodiment according to the invention specifically represents an ideal embodiment of the invention. As a result, various modifications of the illustration are envisaged. The embodiments are thus not limited to the particular form of the region shown, but also include modifications of the form, for example by manufacture.

Hereinafter, with reference to the accompanying drawings, a process connection apparatus and an operating method thereof in a substrate processing process that automates integration of a vertical process which is the processing of substrates in carrier units in which substrates are placed in a vertical position and a horizontal process in which cleaning and drying are performed on a substrate-by-substrate basis for each of substrates in a horizontal position are described in order to improve productivity and quality stability in a chemical processing and a cleaning and drying process of a substrate.

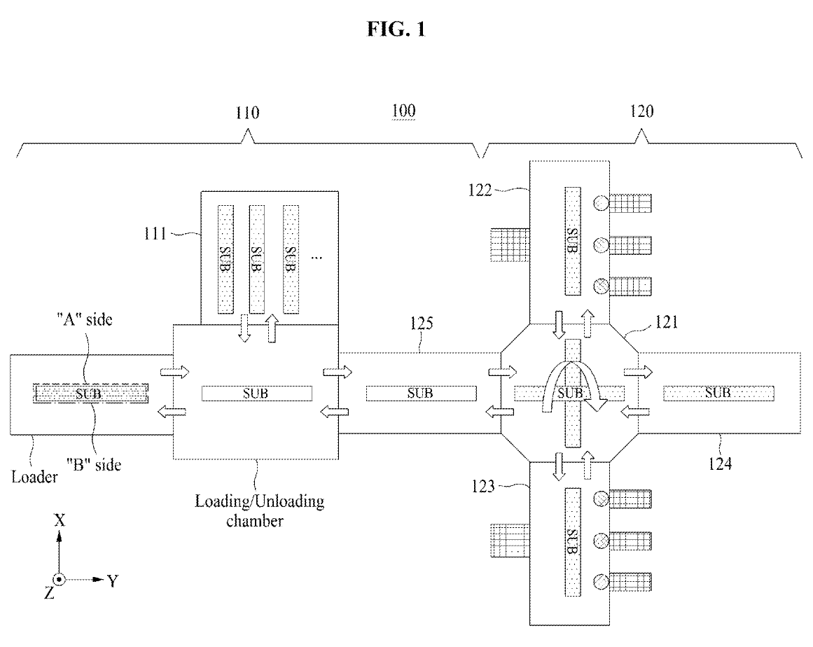

FIG. 1 is a plan view illustrating a substrate processing apparatus according to an embodiment.

Referring to FIG. 1, a substrate processing apparatus 100 according to an embodiment may include a substrate transferring unit 110 and a sputtering unit 120.

Hereinafter, the substrate (SUB) means not only a substrate based on a semiconductor material, but also a base layer composed of various materials to be sputtered.

In addition, a vertical position of the substrate (SUB) hereinafter means a position in which the plane direction of the substrate (SUB) is horizontal direction. That is, the “vertical position” means a position in which a flat large surface of the substrate (SUB) is included in a preset angle range with respect to an imaginary surface orthogonal to the ground. As an example, the “vertical position” may mean a position in which a flat wide surface of the substrate (SUB) is included within an angle range of 45 degrees to 135 degrees with respect to an imaginary surface orthogonal to the ground. The numerical values of the angular ranges are given by way of example only, and the numerical values of the angle ranges forming the condition of the “vertical position” may be set in various ways.

The substrate transferring unit 110 is a component configured to transfer the substrate (SUB) in the vertical position to be loaded to the sputtering unit 120, and is characterized in that magnetic levitation (maglev) is used as a transfer method. To this end, the substrate transferring unit 110 may be configured to magnetically levitate a tray to which the substrate in the vertical position is coupled from a rail and transfer the tray to the sputtering unit 120.

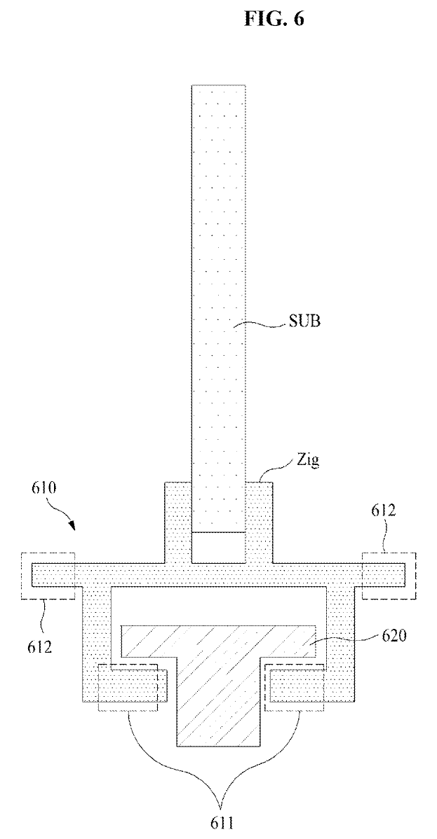

At this time, the tray may include a magnetic generation module having a polarity opposite to that of the rail, and may have a structure that prevents a magnetic field generated in the magnetic generation module or the rail from affecting the substrate (SUB) in the vertical position. A detailed description thereof will be described with reference to FIG. 6.

A buffer 111 for temporarily storing the substrate (SUB) in the vertical position may be provided on one side of the substrate transferring unit 110. The buffer 111 may be omitted according to an implementation example, and the position may also be adaptively adjusted. In an example, the buffer 111 may be provided on one side of the sputtering unit 120, not on one side of a substrate transferring unit 110.

The sputtering unit 120 may include a rotating chamber 121 and at least one sputtering chamber 122, 123 as a component that performs sputtering on at least one surface A of the substrate (SUB) in the vertical position while being connected to one side of the substrate transferring unit 110.

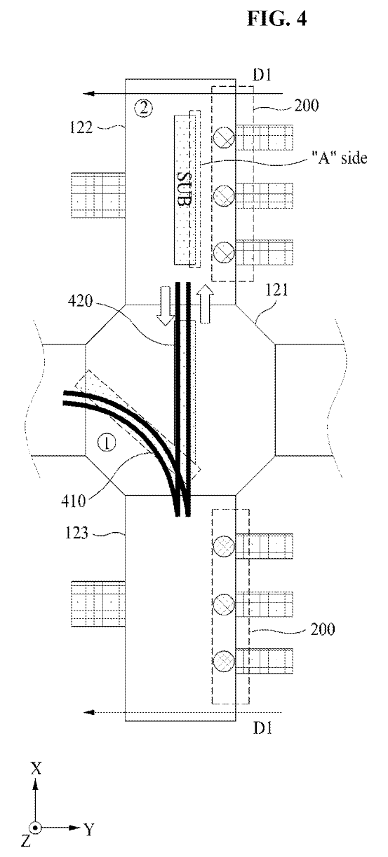

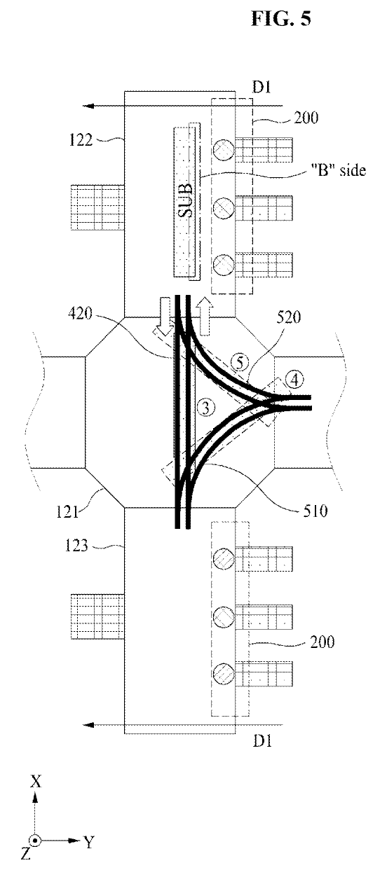

The rotating chamber 121 may be configured to yaw-rotate the substrate (SUB) in the vertical position. In an example, the rotating chamber 121 may include rotating components for allowing the substrate (SUB) in the vertical position to yaw-rotate about a vertical axis. However, without being limited or restricted thereto, the rotating chamber 121 may include a cross design of rails that transfer the substrate (SUB) in the vertical position. A detailed description thereof will be described with reference to FIGS. 4 to 5.

The at least one sputtering chamber 122, 123 is positioned opposite to the rotating chamber 121 and may be provided in two. Accordingly, the rotating chamber 121 may provide the substrate (SUB) in the vertical position by yaw-rotating it to each of the two sputtering chambers 122 and 123 described. However, the example of provision of at least one sputtering chamber 122, 123 is not limited or limited to that described.

In addition, the sputtering unit 120 may further include a pretreatment chamber 124 that performs pretreatment on the one surface A of the substrate (SUB) in the vertical position before performing sputtering while being connected to the one side of the rotating chamber 121, and/or a heat treatment chamber 125 that performs heat treatment on the one surface A of the substrate (SUB) in the vertical position before performing sputtering.

This sputtering unit 120 is characterized in that it is configured to perform double-sided sputtering on both surfaces of the substrate (SUB) in the vertical position. A detailed description thereof will be described below.

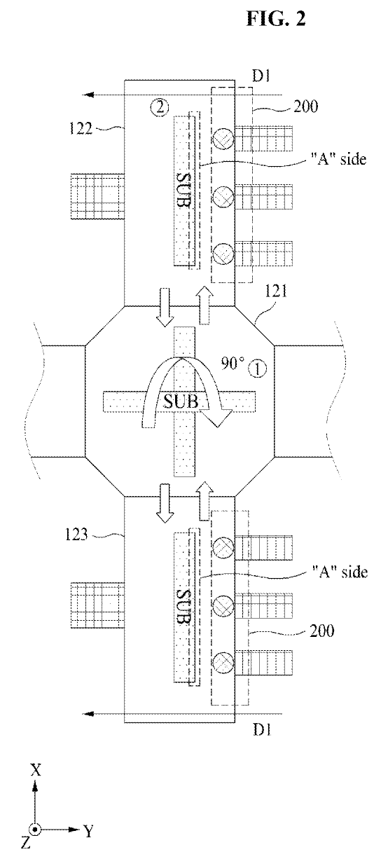

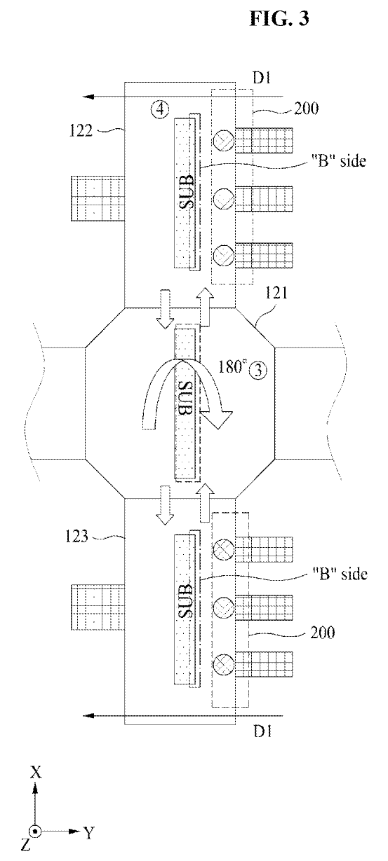

FIGS. 2 to 3 are enlarged plan views of a portion of a sputtering unit to illustrate a rotation function of a rotating chamber including rotation components in the sputtering unit according to an embodiment, where FIG. 2 is a view for describing when sputtering is performed on one surface of a substrate (SUB) in a vertical position, and FIG. 3 is a view for describing when sputtering is performed on the other surface of the substrate (SUB) in the vertical position.

Referring to the drawings, the sputtering unit 120 may perform double-sided sputtering on both surfaces A, B of the substrate (SUB) in the vertical position through the at least one sputtering chamber 122, 123 by yaw-rotating and repeatedly providing the substrate (SUB) in the vertical position to the at least one sputtering chamber 122, 123 configured to sputter a target on one side 200 in the horizontal direction D1 through the rotating chamber 121.

Here, the at least one sputtering chamber 122, 123 may be configured to sputter a target on one side 200 in the horizontal direction D1, as shown in the figures. Hereinafter, the fact that the at least one sputtering chamber 122, 123 is configured to sputter a target on one side 200 in the horizontal direction D1 means that the at least one sputtering chambers 122, 123 have a structure in which a sputtering target is provided on one side 200 which is a side wall of the at least one sputtering chamber 122, 123 so as to be able to sputter the target in the horizontal direction D1 as shown in the figure.

More specifically, when the substrate (SUB) in the vertical position is transferred from the substrate transferring unit 110 as shown in FIG. 1, the sputtering unit 120 may first yaw-rotate the substrate (SUB) in the vertical position in the clockwise direction by 90° in the rotating chamber 121 as shown in FIG. 2 so that one surface A of the substrate (SUB) in the vertical position faces one side 200 in the horizontal direction D1 of sputtering the target in the at least one sputtering chamber 122, 123 (①). Then, as shown in FIG. 2, the sputtering unit 120 may perform sputtering on one surface A by initially providing the substrate in the vertical position to the at least one sputtering chamber 122, 123 such that any one surface A of the both surfaces A, B of the substrate (SUB) in the vertical position faces one side 200 in the horizontal direction D1 in which the target is sputtered in the at least one sputtering chamber 122,123 (②), yaw-rotate the substrate (SUB) of the vertical position by 180° in the rotating chamber 121 as shown in FIG, 3, and then perform sputtering with respect to the other surface B by again providing the substrate (SUB) in the vertical position with the at least one sputtering chamber 122, 123 such that the other surface B of the both surfaces A, B of the substrate (SUB) in the vertical position face one side 200 in a horizontal direction D1 of sputtering the target in the at least one sputtering chamber 122,123 (④), thereby performing double-sided sputtering.

Although the rotation function in the case where the rotating chamber 121 includes the rotation components has been described above, the rotating chamber 121 is not limited thereto and may implement the rotation function by including a cross design of the rails. A detailed description thereof will be described below.

FIGS. 4 to 5 are enlarged plan views of a portion of a sputtering unit to illustrate a rotation function of a rotating chamber including a cross design of rails in the sputtering unit according to an embodiment, FIG. 4 is a view for describing when sputtering is performed on one surface of a substrate (SUB) in a vertical position, and FIG. 5 is a view for describing when sputtering are performed on the other surface of the substrate (SUB) in the vertical position.

Referring to the drawings, the sputtering unit 120 may perform double-sided sputtering by repeatedly providing the both surfaces A, B of the substrate (SUB) in the vertical position to alternately face one side 200 in the horizontal direction D1 for sputtering a target in the at least one sputtering chamber 122, 123 by using a cross design (attached to the rotating chamber 121) of rails for transferring the substrate (SUB) in the vertical position.

Here, the at least one sputtering chamber 122, 123 may be configured to sputter a target on one side 200 in the horizontal direction D1, as shown in the figures. Hereinafter, the fact that the at least one sputtering chamber 122, 123 is configured to sputter a target on one side 200 in the horizontal direction D1 means that the at least one sputtering chambers 122, 123 have a structure in which a sputtering target is provided on one side 200 which is a side wall of the at least one sputtering chamber 122, 123 so as to be able to sputter the target in the horizontal direction D1 as shown in the figure.

More specifically, when the substrate (SUB) in the vertical position is transferred from the substrate transferring unit 110 as shown in FIG. 1, the sputtering unit 120 may transfer the substrate (SUB) in the vertical position to the deactivated sputtering chamber 123 through a cross-designed rail 410 of the rotating chamber 121 as shown in FIG. 4 so that one surface A of the substrate (SUB) in the vertical position may face one side 200 of the horizontal direction D1 in which the target is sputtered in the activated sputtering chamber 122 (①), and then provide the substrate (SUB) in the vertical position to the activated sputtering chamber 122 so that the one surface A faces one side 200 of a horizontal direction D1 of sputtering the target in the activated sputtering chamber 122 through a rail 420 (②), thereby performing sputtering with respect to one surface A.

Thereafter, the sputtering unit 120 may transfer the substrate (SUB) in the vertical position to the deactivated sputtering chamber 123 through the rail 420 of the cross-design of the rotating chamber 121 as shown in FIG. 5 (③), transfer the substrate (SUB) in the vertical position to the outer chamber through a rail 510 (④), and provide the substrate (SUB) in the vertical position to the activated sputtering chamber 122 so that the other surface B faces one side 200 of the horizontal direction D1 of sputtering the target in the activated sputtering chamber 122 through a rail 520 (⑤), thereby performing sputtering on the other surface B. Double-sided sputtering may be performed in this way.

FIG. 6 is an enlarged front view of a portion of a substrate transferring unit to illustrate the substrate transferring unit according to an embodiment.

Referring to FIG. 6, the substrate transferring unit 110 may include, as a structure for using magnetic levitation, a magnetic generation module 611 having a polarity opposite to that of a rail 620 in a tray 610 to which the substrate (SUB) in the vertical position is coupled.

In particular, the tray 610 may include a blocking protrusion structure 612 that blocks the magnetic field from below to prevent the magnetic field generated in the magnetic generation module 611 or the rail 620 from affecting the substrate (SUB) in the vertical position.

This blocking protruding structure 612 may have a shape that protrudes further in the horizontal direction with respect to the magnetic generation module 611 and/or the rail 620 to block the magnetic field from below, and may be formed of an insulating material for blocking the current in the magnetic generation module 611 and/or the rail 620 from flowing into the substrate (SUB) in the vertical position.

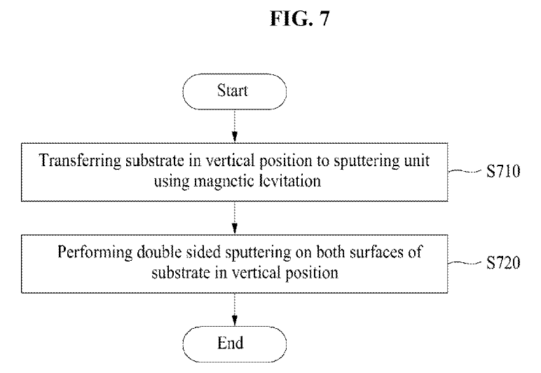

FIG. 7 is a flowchart illustrating a substrate processing method including a substrate transfer method and a sputtering method according to an embodiment.

It is assumed that the substrate processing method described below is performed by the substrate processing apparatus 100 described above.

In step S710, the substrate transferring unit 110 included in the substrate processing apparatus 100 may transfer a substrate (SUB) in a vertical position to the sputtering unit 120 included in the substrate processing apparatus by using magnetic levitation.

Accordingly, in step S720, the sputtering unit 120 may perform double-sided sputtering on both surfaces A, B of the substrate (SUB) in the vertical position.

Although the above embodiments have been described by way of limited embodiments and drawings, various modifications and variations are possible from the above description to those skilled in the art. For example, suitable results may be achieved even if the described techniques are performed in a different order than the described method, and/or components of the described system, structure, apparatus, circuitry, etc. are combined or integrated in a different form than the described method or replaced or substituted by other components or equivalents.

Therefore, other implementations, other embodiments, and equivalents to the claims also fall within the scope of the following claims.

### DESCRIPTION OF SYMBOLS

100 Substrate processing apparatus

110 Substrate transferring unit

111 Buffer

120 Sputtering unit

121 Rotating chamber

122, 123 At least one sputtering chamber

124 Pretreatment chamber

125 Heat treatment chamber

What is claimed is:

1. A substrate processing apparatus, comprising:
a substrate transferring unit that transfers a substrate in a vertical position to a sputtering unit using magnetic levitation; and
the sputtering unit that performs double-sided sputtering on both surfaces of the substrate in the vertical position while being connected to one side of the substrate transferring unit.

2. The apparatus of claim 1,
wherein the substrate transferring unit is configured to magnetically levitate a tray on which the substrate in the vertical position is coupled from a rail and transfer it to the sputtering unit.

3. The apparatus of claim 2,
wherein the tray includes:
a magnetic generation module having an opposite polarity to the rail, and
has a structure that prevents a magnetic field generated in the magnetic generation module or the rail from affecting the substrate in the vertical position.

4. The apparatus of claim 3,
wherein the tray includes:
a blocking protrusion structure that blocks the magnetic field from below to prevent the magnetic field generated in the magnetic generation module or the rail from affecting the substrate in the vertical position.

5. The substrate processing apparatus of claim 1, further comprising:
wherein the vertical position of the substrate means a position in which a plane direction of the substrate is a horizontal direction.

6. The apparatus of claim 1,
wherein the sputtering unit performs the double-sided sputtering by yaw-rotating and repeatedly providing the substrate in the vertical position with at least one sputtering chamber configured to sputter a target on one side in a horizontal direction.

7. The apparatus of claim 6,
wherein the sputtering unit initially provides the substrate in the vertical position to the at least one sputtering chamber so that any one of both surfaces of the substrate in the vertical position faces one side of the horizontal direction sputtering the target in the at least one sputtering chamber, yaw-rotates the substrate in the vertical position by 180° in a rotating chamber provided independently from the sputtering chamber, and then again provides the substrate in the vertical position to the at least one sputtering chamber so that the other one of the both surfaces of the substrate in the vertical position faces one side of the horizontal direction sputtering the target in the at least one sputtering chamber, thereby performing the double-sided sputtering.

8. The apparatus of claim 1,
wherein the sputtering unit performs the double-sided sputtering by repeatedly providing that both surfaces of the substrate in the vertical position alternately face one side in the horizontal direction sputtering the target in the at least one sputtering chamber, using a cross design of rails for transferring the substrate in the vertical position.

9. The apparatus of claim 1,
wherein the substrate transferring unit further includes:
a buffer for temporarily storing the substrate in the vertical position.

10. A substrate processing method of a substrate processing apparatus, the substrate processing method comprising:
a step of transferring, in a substrate transferring unit included in the substrate processing apparatus, a substrate in a vertical position to a sputtering unit included in the substrate processing apparatus using magnetic levitation; and
a step of performing, in the sputtering unit connected to one side of the substrate transferring unit, double-sided sputtering on both surfaces of the substrate in the vertical position.
